(19) United States
(12) Patent Application Publication
(10) Pub. No.: US 2016/0027668 A1
(43) Pub. Date: Jan. 28, 2016

(54) CHEMICAL MECHANICAL POLISHING APPARATUS AND METHODS

(71) Applicant: Applied Materials, Inc., Santa Clara, CA (US)

(72) Inventors: Thomas H. Osterheld, Mountain View, CA (US); Rajeev Bajaj, Fremont, CA (US)

(21) Appl. No.: 14/341,762

(22) Filed: Jul. 25, 2014

(51) Int. Cl. H01L 21/67; H01L 21/3105; H01L 21/321; H01L 21/306

(52) U.S. Cl. CPC H01L 21/67075; H01L 21/30625; H01L 21/31055; H01L 21/3212; H01L 21/67092

(57) ABSTRACT

Embodiments of the invention provide a non-uniform substrate polishing apparatus that includes a polishing pad with two or more zones, each zone adapted to apply a different slurry chemistry to a different area on a substrate to create a film thickness profile on the substrate having at least two different film thicknesses. Polishing methods and systems adapted to polish substrates are also provided, as are numerous other aspects.

### FIELD

The present invention relates generally to electronic device manufacturing, and more particularly to methods and apparatus adapted to polish a substrate surface.

### BACKGROUND

Within semiconductor substrate manufacturing, a chemical mechanical polishing (CMP) process can be used to remove various layers, such as silicon, oxides, copper, or the like. Such polishing (e.g., planarization) can be accomplished by pressing a rotating substrate held in a holder (e.g., polishing head or carrier) against a rotating polishing pad while a slurry is applied uniformly ahead of the substrate (e.g., patterned wafer). The slurry commonly includes a mixture of oxidants, metal oxide abrasive particles, etchants, complexing agents, and corrosion inhibitors. Thus, during polishing, a continuous process of oxidation by oxidants and material removal by abrasive particles and etchants is carried out by the slurry and polishing process. During this polishing process, precise control of the amount of material removal from the substrate is sought. However, given the limitations of existing processes, it is difficult to achieve precise control, especially for removal of small layer thicknesses. Accordingly, what is needed are improved polishing apparatus, systems, and methods.

### SUMMARY

In some embodiments, a non-uniform substrate polishing apparatus is provided. The substrate polishing apparatus includes a polishing pad having two or more zones, each zone adapted to apply a different slurry chemistry to a different area on a substrate to create a film thickness profile on the substrate having at least two different film thicknesses.

In some other embodiments, a substrate polishing system is provided. The system includes a substrate holder adapted to hold a substrate; an a polishing pad having two or more zones, each zone adapted to apply a different slurry chemistry to a different area on a substrate to create a film thickness profile on the substrate having at least two different film thicknesses.

In yet other embodiments, a method of polishing a substrate is provided. The method includes rotating a substrate in a substrate holder against a moving polishing pad; applying different slurry chemistries having different functions separately to at least two different zones of the polishing pad; and removing different amounts of material from different areas of the substrate corresponding to the at least two different zones of the polishing pad.

In still yet other embodiments, a substrate polishing system is provided. The system includes a substrate holder adapted to hold a substrate; a polishing platform having a polishing pad moveable relative to the substrate; and a distribution system adapted to dispense, in a timed sequence, at least two different slurry chemistries selected from a group consisting of a material preservation slurry chemistry, a slow material removal slurry chemistry, and an aggressive material removal chemistry.

In other embodiments, a system for polishing a substrate is provided. The system includes a processor; a memory coupled to the processor and storing instructions executable on the processor, the instructions adapted to cause the system to: rotate a substrate in a substrate holder against a moving polishing pad; apply different slurry chemistries having different functions separately to at least two different zones of the polishing pad; and remove different amounts of material from different areas of the substrate corresponding to the at least two different zones of the polishing pad.

Other features and aspects of the present invention will become more fully apparent from the following detailed description of example embodiments, the appended claims, and the accompanying drawings.

### BRIEF DESCRIPTION OF THE DRAWINGS

FIG. 1A illustrates a schematic top view of a linear substrate polishing apparatus according to embodiments.

FIG. 1B illustrates a schematic cross-sectioned side view of a linear substrate polishing apparatus according to embodiments taken along section line 1B-1B of FIG. 1A.

FIG. 1C illustrates a schematic cross-sectioned side view of a linear substrate polishing apparatus according to embodiments taken along section line 1C-1C of FIG. 1A.

FIG. 2A illustrates a schematic top view of a rotary substrate polishing apparatus according to embodiments.

FIG. 2B illustrates a schematic side view of a rotary substrate polishing apparatus according to embodiments.

FIG. 3A illustrates a top view of a slurry distributor according to embodiments.

FIG. 3B illustrates a side view of a slurry distributor according to embodiments.

FIG. 3C illustrates a first end view of a slurry distributor according to embodiments.

FIG. 3D illustrates a second end view of a slurry distributor according to embodiments.

FIGS. 3E-3G illustrate various cross section view of a slurry distributor according to embodiments.

FIG. 4 illustrates a flowchart of a method of polishing a substrate according to embodiments.

FIG. 5 illustrates a flowchart of a method of polishing a substrate according to embodiments.

FIG. 6 illustrates a graph of phases (e.g., pulses) of a method of polishing a substrate according to embodiments.

FIG. 7 illustrates a graph of phases (e.g., pulses) of another method of polishing a substrate according to embodiments.

FIGS. 8 and 9 are illustrations depicting a portion of an example film thickness profile on a substrate before and after non-uniform polishing methods have been applied according to embodiments.

FIG. 10 is a top view of a substrate polished to have a non-uniform thickness profile according to embodiments.

FIG. 11 illustrates a schematic top view of a linear non-uniform substrate polishing apparatus according to embodiments.

FIG. 12 is a schematic top view of a wedge-shaped polishing pad positioned on a substrate according to embodiments.

FIG. 13 illustrates a flowchart of an example method of non-uniformly polishing a substrate according to embodiments.

### DETAILED DESCRIPTION

Embodiments described herein relate to apparatus, systems and methods useful for, and adapted to, polishing a surface of a substrate in semiconductor device manufacturing.

Prior systems have utilized slurry including a mix of slurry components. The components of the slurry are adapted to accomplish various processes on the substrate, such as the process of oxidation of the substrate surface by oxidants and material removal by abrasive particles and etchants. In a typical small removal process adapted to remove less than about 250 Angstroms, the across the wafer removal variations can be as high as 50%-100% of the film thickness that is removed. With advancing technology, thinner and thinner films are being applied and can be undergo polishing. For example, films used in the formation of front end structures, such as inlaid metal gates and the like are very thin. As these films are provided in the device structures, it is desired that these thin films be removed with a relatively high degree of uniformity and control. Accordingly, as films get thinner, less material removal is accomplished by the CMP, and more precision is desired in the removal process. In the extreme case of atomic layer deposition (ALD), where film thickness is measured in atomic layers (e.g., Angstroms), the material removal precision is also desired to be on the order of an atomic layer.

Therefore, there is a need for a polishing apparatus and methods that enables removal of thin films, wherein such removal is accomplished with very high uniformity. Furthermore, it is desired that the method can offer precise control of the removal process, i.e. the relative amount of removal. In some embodiments of the invention, the slurry components are physically separate. This can be used to provide more precise control over the amount of material removal. By physically (e.g., spatially) separating the slurry components, the polishing process can be provided with distinct breaks (e.g., formed as physical zones of slurry components having differing chemical composition) between two or more of the slurry components (e.g., accomplishing oxidation, material removal, and corrosion inhibition).

For example, in some embodiments, a polishing platform (e.g., comprising a pad support and pad) can be separated to have two or more zones, wherein each zone is adapted to contain a different slurry component. Each slurry component can have a different chemical composition. During polishing, the substrate can be moved or rastered (e.g., translated) across the zones wherein each adjacent zone includes a different slurry component. Running one cycle across the zones, in sequence, can be used to effectively remove one atomic layer, for example. Total material removal can be precisely controlled by managing the number of cycles. Removal can be controlled on an atomic level.

In some embodiments, the polishing surface is separated (e.g., broken up) into multiple zones, wherein each zone contains an individual slurry component that performs one of an oxidation, material removal, or corrosion inhibition process. By rastering (e.g., scanning) across these separated zones, high cycle counts can be achieved within reasonable total polish time. For example, within an oxidation zone containing the oxidation slurry component, oxidants function to oxidize the surface layer of substrate. This oxidation process can be self-limiting, since only a surface layer is exposed to oxidants. Within the material removal zone containing, for example, the removal and etchant slurry component, abrasives and etchants attack the previously-oxidized surface layer. The material removal zone can be adjacent to the oxidation zone. This material removal process can also be self-limiting, since only the oxidized layer is removed. A corrosion inhibiting zone containing a corrosion inhibiting slurry component (e.g., including corrosion inhibiters) operates on the previously abraded surface layer to limit corrosion thereof. The corrosion inhibiting zone can be provided adjacent to the oxidation zone.

In another aspect, rather than being separated physically, the application of the slurry components are separated in time. Thus, in one aspect, embodiments of the invention disclose a polishing process (e.g., a film removal process), which utilizes multi-step reactions to affect uniform film removal. In particular, embodiments of the invention separate the slurry components in time by introducing them separately and in a timed sequence. This can be used to provide more precise control over amount of material removal. This multi-step polishing process can be applied to any application where the CMP involves competing reactions.

Thus, in this aspect, the polishing process will have distinct breaks (e.g., separations in time) between administering of the various slurry components used to accomplish oxidation, material removal, and/or corrosion inhibition processes. In one or more embodiments, the oxidiation slurry component can be first introduced in time, followed by a material removal slurry component (e.g., containing abrasives and/or etchants). This can be followed in sequence by introducing a corrosion inhibitor slurry component in some embodiments. The sequence can be followed by introduction of a rinsing liquid (e.g., de-ionized (DI) water) in some embodiments. In other embodiments, the rinsing liquid can be introduced between the various slurry introductions phases. These slurry components can be administered between the substrate and the polishing pad during the polishing process, as will be further explained herein.

Further, in some embodiments, using non-uniform concentrations and/or applications of slurry chemistries, non-uniform removal or even localized removal of material can be achieved. In other words, unlike the above-mentioned embodiments, other embodiments of the present invention can be used to selectively remove only partial areas of films on the surface of a substrate. For example, a desired number of layers of material outside of a predefined radius from the center of a substrate can be removed while the same layers of material within the radius can be left on the substrate. Thus, embodiments of the present invention include applying radially differing amounts of chemistry or applying different timings of the application of the chemistry to achieve non-uniform removal (or different amounts of removal) depending on the substrate radius. This can be achieved by using different amounts of chemistry delivered to the location on the pad which corresponds to the target radii of the substrate where films are to be removed while concurrently not applying the removal chemistry (or applying different chemistry) to areas of the pad corresponding to substrate areas that are to not undergo film removal. For example, a region of the substrate where less removal is desired could have more additive (e.g., suppressant) added to the corresponding region of the pad. Similarly, less oxidizer could also be supplied to this region or possibly more or less deionized water depending on the effect of water on the removal. Similarly, less of the abrasive slurry could be supplied to this region or more diluted slurry could be supplied to this region.

In some alternative embodiments, a pad smaller than the substrate can be used and material can be removed using localized motion of the pad in the presence of slurry. The concept of the above Atomic Layer Polishing (ALP) embodiments can be implemented to provide additional control of the localized removal process. For example, by only applying removal chemistry to a center area of a smaller polishing pad positioned at the center of a rotating substrate, the effective diameter of pad for removing material can be made smaller than the polishing pad's actual diameter. Further, if a smaller polishing pad is disposed at an offset from the center of a rotating substrate, a ring-shaped area between an inner radius and an outer radius can be isolated for material removal. The width of the ring-shaped removal area can be controlled based upon the radius of the pad area to which removal chemistry is applied.

In some other alternative embodiments, stationary polishing pads having shapes other than a circular shape can be used. For example, in order to compensate for the varying speed of rotation at different radii of a rotating substrate, a wedge-shaped pad can be used to polish the rotating substrate. In other words, a wedge-shaped pad can be used to insure that substrate area rotating relatively quickly (e.g., at a large radius nearer the outer edge) experiences exposure to removal chemistry on the pad equal to area moving relatively slowly (e.g., at a small radius nearer the center of the rotating substrate).

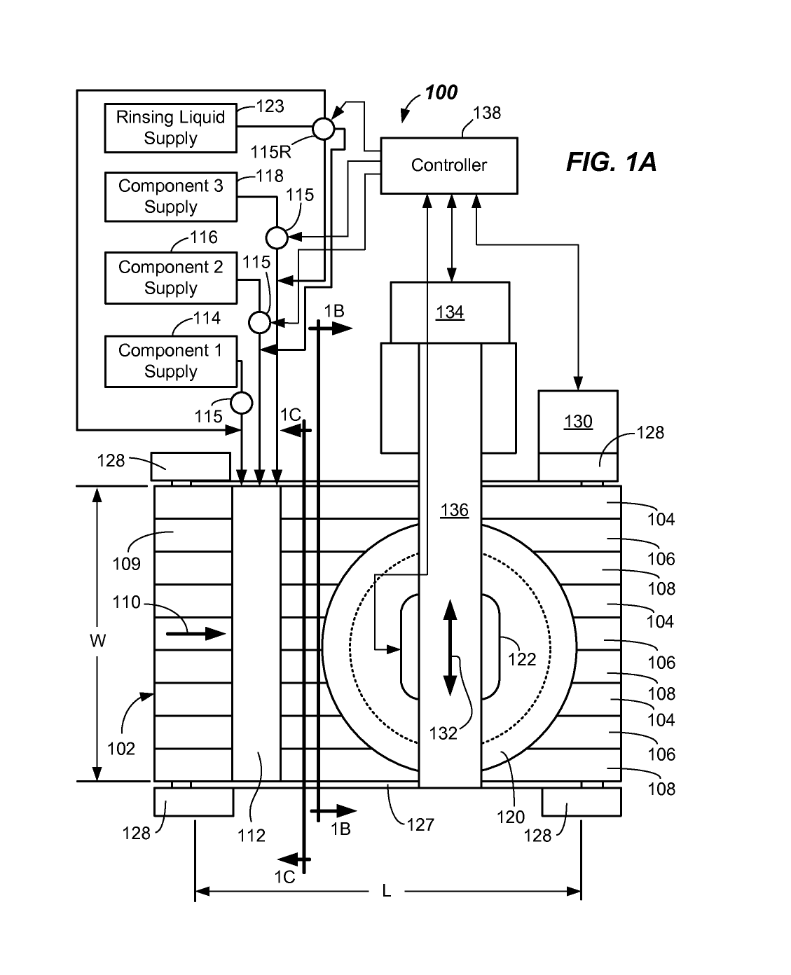

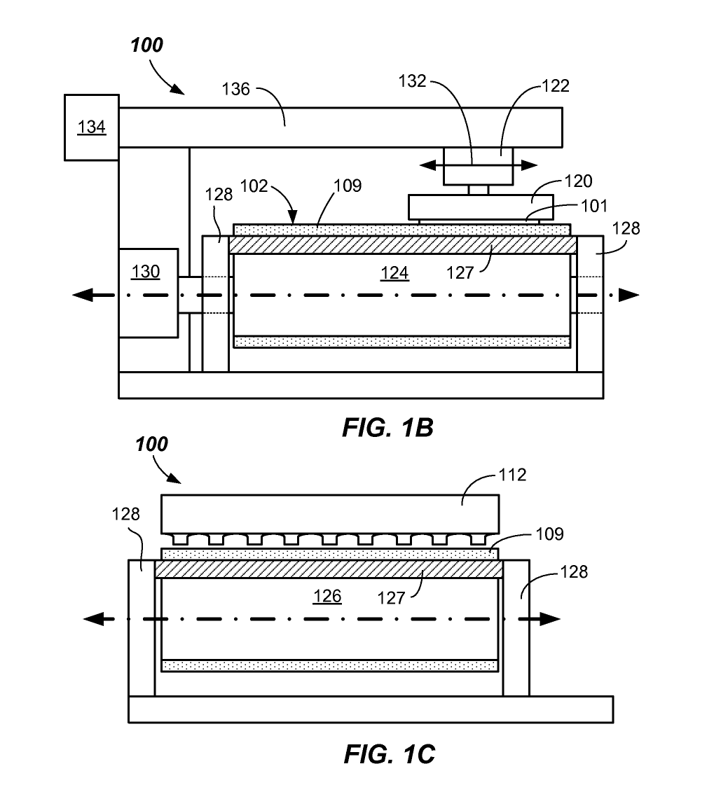

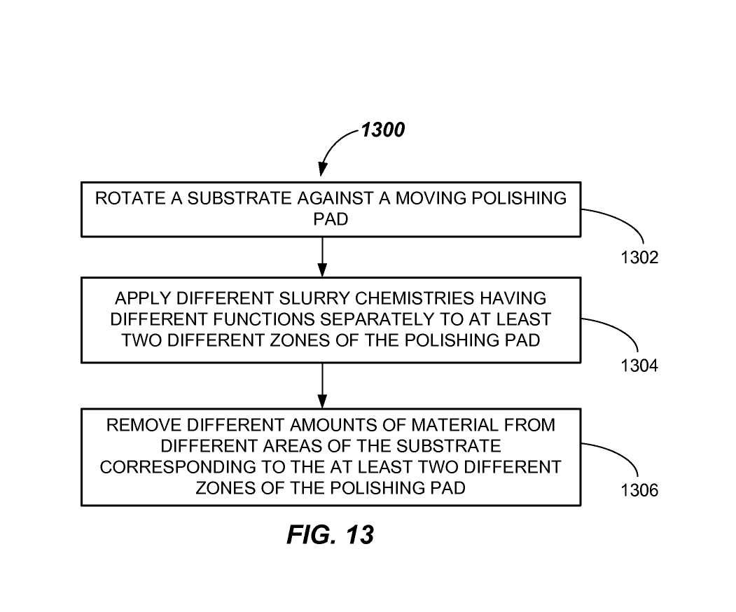

These and other aspects of embodiments of the invention are described below with reference to FIGS. 1A-13 herein.

FIGS. 1A-1C illustrate various views of a substrate polishing apparatus 100 and components thereof. The substrate polishing apparatus 100 is adapted to hold and polish a substrate 101 as will be apparent from the following description. The substrate polishing apparatus 100 includes a polishing platform 102 having two or more physical zones, such as first zone 104, second zone 106, and third zone 108. The two or more zones (e.g., 104, 106, and 108) are adapted to contain a different slurry component having a different chemistry (chemical composition). The two or more zones can be arranged across a width “W” of the platform 102. In the depicted embodiment, nine zones are shown. However, more or less numbers of zones can be provided. There can be multiple zones that are non-adjacent, but that contain a slurry component having the same chemistry. In the depicted embodiment, the platform 102 comprises a linear polishing platform wherein the two or more zones are arranged across a width “W” of a pad 109 and that extend along the length “L” of the pad with the length L being substantially longer than the width W. In the depicted embodiment, the pad 109 of the platform 102 moves linearly as indicated by directional arrow 110.

During the polishing method, various slurry components, such as slurry component 1, slurry component 2, and slurry component 3 can be applied to the pad 109 by a distributor 112. The distributor 112 can have any suitable internal structure capable of dispensing the slurry components to the two or more zones (e.g., to zones 104, 106, 108). The slurry component 1, slurry component 2, and slurry component 3, for example, can be received from slurry component supplies 114, 116, 118, respectively. More or less numbers of slurry components can be provided. The supply of slurry components to the distributor 112 can be accomplished by a distribution system having one or more suitable pumps or other flow control mechanisms 115. “Slurry component” as used herein means a processing medium that is adapted to carry out one or more designated polishing functions. In some embodiments, a rinsing liquid (e.g., de-ionized water) can be provided from the rinsing liquid source 123 and inserted between two or more of the zones, such as between zone 104 and 106, or between 106 and 108, or between both zones 104 and 106 and zones 106 and 108. Any suitable construction of the distributor 112 can be used to accomplish this separation of the zones 104, 106, 108 by a rinsing liquid zone.

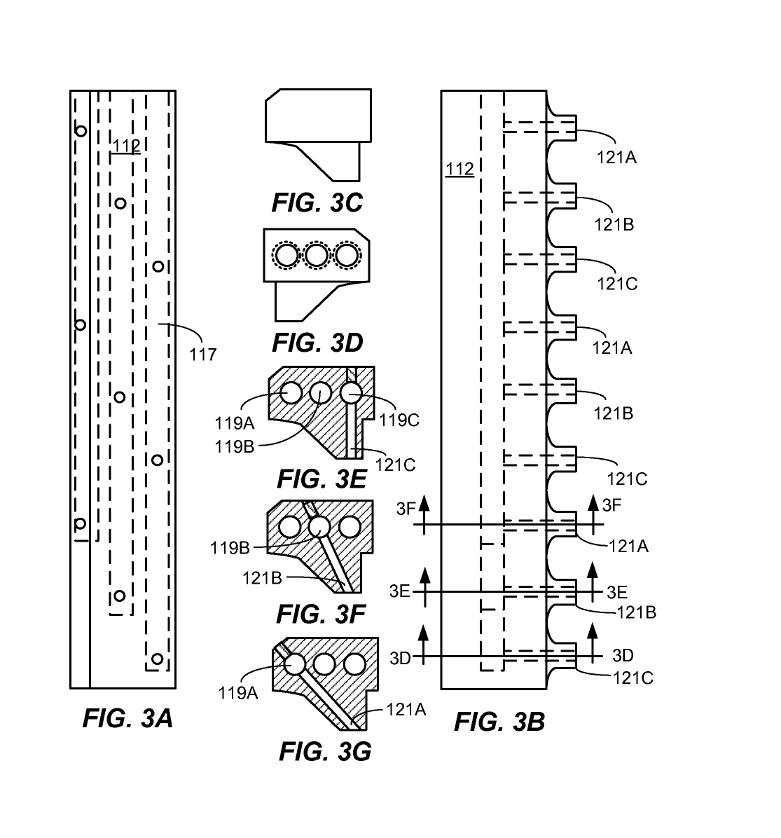

For example, slurry component 1 can comprise a material adapted to execute a surface modification function, such as oxidation or other surface modification such as the formation of a nitride, bromide, chloride, or hydroxide containing later. Slurry component 1 can contain a liquid carrier such as purified water, and an oxidant such as hydrogen peroxide, ammonium persulfate, or potassium iodate. Other surface modifying materials can be used. Slurry component 1 can be supplied to the first zone 104 of the pad 109 from the component supply 1 114 through a first channel 119A (FIG. 3G) of the distributor 112, for example.

Slurry component 2 can comprise a material adapted to execute a material removal function. Slurry component 2 can contain a liquid carrier such as purified water, and abrasive media such as silicon dioxide or aluminum oxide. The abrasive can have an average particle size between about 20 nanometers and 0.5 microns. Other particle sizes can be used. Slurry component 2 can also include an etchant material such as carboxylic acid, or an amino acid. Other etchant or complexing agent materials can be used. Slurry component 2 can be supplied from the component supply 2 116 to the second zone 106 of the pad 109 by a second channel 119B (FIG. 3F) of the distributor 112, for example.

In one or more embodiments, slurry component 3 can comprise a material adapted to execute a corrosion inhibition function. Slurry component 3 can contain a liquid carrier such as purified water, and corrosion inhibitor such as benzotriazole, or 1,2,4 Triazole. Slurry component 3 can be supplied from the component supply 3 118 to the third zone 108 of the pad 109 by a third channel 119C (FIG. 3E) of the distributor 112, for example.

The zones 104, 106, 108 can be arranged in a side by side fashion and can each have a width of between about 2 mm and 50 mm. The widths can be the same as or different from each other. Other widths can be used.

In one or more embodiments, a distribution system including a distributor 112 is adapted to dispense into the two or more zones (e.g., zone 104, 106) at least two different slurry components. The slurry components can be selected from a group consisting of a surface modification slurry component, and a material removal slurry component, as discussed above.

In one or more embodiments, the distributor 112 can be formed as a unitary component and can be positioned adjacent to the pad 109 (e.g., just above the pad 109). The distributor 112 can provide delivery of the slurry components concurrently through two or more outlets (e.g., through outlets 121A, 121B, and 121C). For example, as shown in FIG. 3A-3G, the distributor 112 can be part of a distribution system that can include multiple channels, such as a first channel 119A extending along a length of the distributor body 117. First channel 119A is adapted to distribute the slurry component 1 from component 1 supply 114 to one or more first distribution outlets 121A that are fluidly coupled to the first channel 119A along its length.

The distributor 112 can also include a second channel 119B extending along the length of the distributor body 117 and adapted to distribute the slurry component 2 from component 2 supply 116 to one or more second distribution outlets 121B that are fluidly coupled to the second channel 119B along its length.

The distributor 112 can also include a third channel 119C extending along the length of the distributor body 117 and adapted to distribute the slurry component 3 from component 3 supply 118 to one or more second distribution outlets 121C that are fluidly coupled to the third channel 119C along its length. Other channels and interconnected outlets can be provided to disburse other slurry components and/or a rinsing liquid.

In some embodiments, the rinsing liquid can be received in a separate separation zone to separate the disbursed slurry components. The outlets 121A, 121B, 121C can have a diameter of less than about 5 mm, or between about 1 mm and 15 mm in some embodiments. A pitch (e.g., spacing between the adjacent outlets) can be less than about 50 mm, less than about 25 mm, or even less than about 10 mm in some embodiments. In some embodiments, the pitch can be between about 2 mm and 50 mm. Other diameters and pitches can be used.

In other embodiments, the distributor can be comprised of separate distributor heads, one for each slurry component that can be arranged at different spatial locations on the pad 109. A rinsing liquid (e.g., DI water) can be delivered through some or all of the outlets 121A-121C, or through separate outlets specifically designed for the rinsing liquid. Rinsing liquid can be provided from rinsing liquid supply 123 to some or all of each of the outlets 121A-121C by controlling valve 119S. Optionally, the rinsing liquid can be provided by a separate distributor head or separate outlets from the distributor 112.

In another embodiment, the distributor can be included in the pad support 127 of the platform 102. In this embodiment, the slurry components 1, 2, 3 can be disbursed to the various zones 104, 106, and 108 from underneath the pad 109. The pad support 127 can include holes like the outlets 121A-121C in distributor 112 being arranged across the width of the pad 109. Each hole can be fluidly coupled to one of the slurry component supplies 114, 116, 118. The various separated slurry components 1, 2, 3 can pass though the holes and wick through the pad 109 containing an internal porous structure of connected open pores as the pad 109 is rotated on the rollers 124, 126. The wicking provides the slurry components 1, 2, 3 to the one or more zones 104, 106, 108, respectively. Rinsing liquid can also be disbursed through some or all of the holes.

Again referring to FIGS. 1A-1C, as the slurry components are being supplied to the zones 104, 106, 108 of the pad 109, a substrate holder 120 of the substrate polishing apparatus 100 can be rotated. Substrate holder 120 is adapted to hold the substrate 101 in contact with the pad 109 and rotate the substrate 101 as the polishing takes place. Other motions can be provided in addition or in place of the rotation, such as orbital motion. Rotational speed can be between about 10-150 RPM, for example. Rotation can be accomplished by driving the holder 120 with a holder motor 122. Any suitable motor can be used. An applied pressure on the substrate 101 during polishing can be between about 0.1 psi and 1 psi, for example. Any suitable conventional mechanism for applying the pressure can be used, such as a spring-loaded mechanism or other suitable vertically-acting actuator. Other rotational speeds and pressures can be used. Substrate holders (also referred to as retainers or carrier heads) are described in U.S. Pat. No. 8,298,047; U.S. Pat. No. 8,088,299; U.S. Pat. No. 7,883,397; and U.S. Pat. No. 7,459,057, issued to the present assignee, for example.

As the slurry components 1, 2, 3 are applied to the respective zones 104, 106, 108, the pad 109 can be moved in the direction of the arrow 110. The linear speed of movement of the pad 109 in the direction of arrow 110 can be between about 40 cm/sec and about 600 cm/sec, for example. Other speeds can be used. The pad 109, as best shown in FIGS. 1B and 1C, can be provided in the form of a continuous or endless belt. The pad 109 can be supported at its ends by first and second rollers 124, 126 (e.g., cylindrical rollers) and underneath the top portion of the pad 109 by a pad support 127 spanning the width of the pad 109. Rollers 124, 126 can be supported for rotation on a frame 128 by bearings or bushings, or other suitable low friction devices, for example. One of the rollers, such as roller 126, can be coupled to a pad drive motor 130 which can be driven at the appropriate rotational speed to accomplish the linear polishing speed of the pad 109 described above. Pad support 127 can also be coupled to the frame 128 at one or more locations and can support the upper portion of the pad 109 underneath some or most of the length L of upper surface of the pad 109.

In addition to the rotation of the substrate holder 120, and the motion of the pad 109, the holder 120 can be translated in the direction of directional arrow 132. The translation can be an oscillation back and forth along the transverse direction 132, generally perpendicular to the linear motion of the pad 109. Translation can be caused by any suitable translation motor 134 and drive system (not shown) that moves the substrate holder 120 back and forth along a support beam 136. The drive system adapted to accomplish the translation can be a rack and pinion, chain and sprocket, belt and pulley, drive and ball screw, or other suitable drive mechanism. In other embodiments, an orbital motion can be provided by a suitable mechanism. The rotation of the pad 109, rotation and translation (e.g., oscillation) of the substrate holder 120, and the distribution flow of the slurry components 1, 2 and 3 and rinsing liquid 123 can be controlled by controller 138. Controller 138 can be any suitable computer and connected drive and/or feedback components adapted to control such motions and functions.

The pad 109 can be made of a suitable polishing pad material, for example. The pad 109 can be a polymer material, such as polyurethane, and can have open surface porosity. Surface porosity can be open porosity and can have an average pore size of between about 2 microns and 100 microns, for example. Pad can have a length L, as measured between the centers of the rollers 124, 126, of between about 30 cm and 300 cm, for example. Other dimensions can be used.

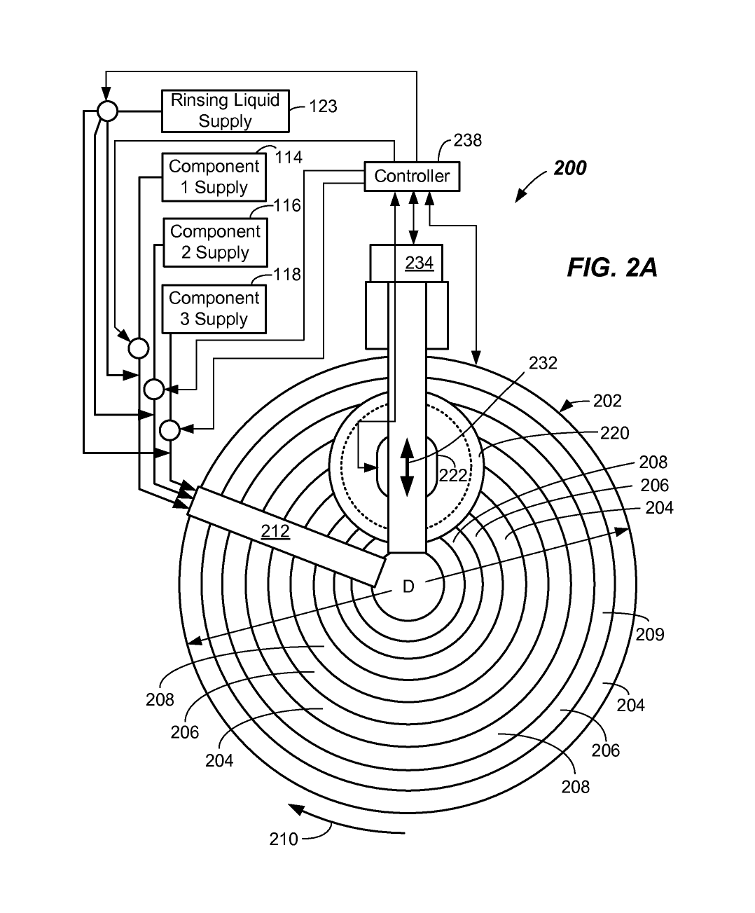

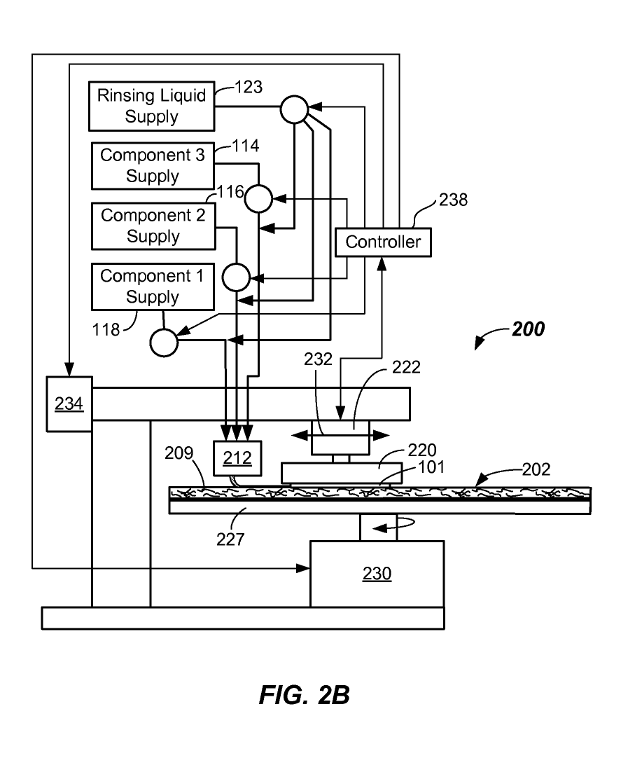

FIGS. 2A and 2B illustrate various views of an alternative embodiment of a substrate polishing apparatus 200 and components thereof. As before, the substrate polishing apparatus 200 is adapted to hold and polish a substrate 101 as will be apparent from the following description. The substrate polishing apparatus 200 includes a polishing platform 202 having a pad 209 and a pad support 227 (e.g., a platen). The polishing platform 202 has two or more physical zones, such as first zone 204, and second zone 206, and even a third zone 208. Zones 204, 206, 208 in this embodiment are arranged as concentric annuli, and the platform 202 is rotatable.

Each zone 204, 206, 208 is adapted to contain a different slurry component having a different chemistry, such as slurry components 1-3 described above. The slurry components can be dispensed to the various zones 204, 206, 208 by a distributor 212 coupled to the component supplies 114, 116, 118, via valves or other flow control mechanism as commended by controller 238 as described before. The two or more zones 204, 206, 208 can be arranged across a diameter “D” of the platform 202. The width of each annular zone can be the same or different and of a width, and can be as described above. In the depicted embodiment, nine annular zones are shown. However, more or less numbers of zones can be provided. Furthermore, there can be multiple zones that are not adjacent to each other, but that contain a slurry component having a same chemistry (e.g., chemical composition). For example, each of the zones labeled 204 can receive and contain the same slurry chemistry. Each of the zones labeled 206 can receive and contain the same slurry chemistry, and each of the zones labeled 208 can receive and contain the same slurry component chemistry. However, the chemistries in each of the zones 204, 206 and 208 can have different slurry component chemistries as compared to each other.

In the depicted embodiment, the platform 202 comprises a rotary polishing platform wherein the two or more zones (e.g., zones 204, 206 or 204, 206 and 208) are arranged across a diameter D the pad 209. The platform 202 and pad 209 can be rotated in the direction of directional arrow 210 at rotational speed of between about 10 and about 200 RPM by a platform motor 230. As before, the substrate holder 220 can be rotated by a suitable holder motor 222 to rotate the substrate 101 as the polishing takes place. Rotational speed of the holder 220 can be between about 10 RPM-200 RPM, for example. Similarly, the holder 220 can be translated (e.g., oscillated) back and forth along the transverse direction 232, generally perpendicular to the tangential motion of the pad 209. Translation can be caused by any suitable translation motor 234 and drive system (not shown) as described above.

An applied pressure on the substrate 101 during polishing can be as discussed above, for example. Any suitable conventional mechanism for applying the pressure can be used, such as a spring-loaded mechanism or actuator. Other rotational speeds and pressures can be used. Substrate holder 220 can be as described in U.S. Pat. No. 8,298,047; U.S. Pat. No. 8,088,299; U.S. Pat. No. 7,883,397; and U.S. Pat. No. 7,459,057, for example.

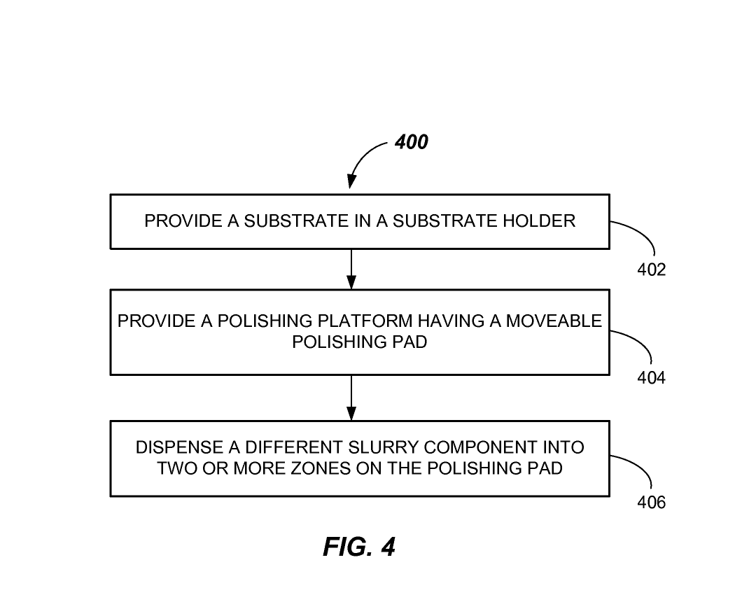

FIG. 4 illustrates a method 400 of processing a substrate (e.g., substrate 101), and in particular a method of polishing a surface (e.g., a front side or backside surface) of a substrate 101 (e.g., a patterned or unpatterned wafer). The method 400 includes, in 402, providing a substrate in a substrate holder (e.g., substrate holder 120, 220), providing, in 404, a polishing platform (e.g., polishing platform 102, 202) having a moveable polishing pad (e.g., polishing pad 109, 209), and, in 406, dispensing a different slurry component into two or more zones (e.g., zones 104, 106, 108) on the polishing pad. The polishing pad can be of a linear moving version pad 109 or a rotationally moving version pad 209. The slurry components can be disbursed to the zones (e.g., zones 104, 106, 108) above the pad 109 or below the pad 109 (e.g., by wicking or other capillary action).

In another aspect, a substrate polishing system is provided as described in either of FIG. 1A-1C or 2A and 2B. The substrate polishing system includes and apparatus 100, 200 with a polishing holder 120, 220 adapted to hold a substrate 101, a polishing platform 102, 202 having a polishing pad 109, 209 moveable relative to the substrate 101, and a distribution system adapted to dispense at least two different slurry components selected from a group consisting of an oxidation slurry component, a material removal slurry component, and a corrosion inhibiting slurry component. In this aspect, rather than being distributed into zones arranged across the width W or diameter D of the pad 109, 209, the two or more slurry components are dispensed in a timed sequence, one after another.

In accordance with this aspect, a first slurry component selected from the group consisting of an oxidation slurry component, a material removal slurry component, and a corrosion inhibiting slurry component is first dispensed onto the pad (e.g., pad 109, 209). After a predetermined amount of time has elapsed, the supply of the first slurry component is stopped, and a second slurry component selected from the group consisting of an oxidation slurry component, a material removal slurry component, and a corrosion inhibiting slurry component is then dispensed onto the pad (e.g., pad 109, 209). After another predetermined amount of time has elapsed, the supply of the second slurry component is stopped, and a third slurry component selected from the group consisting of an oxidation slurry component, a material removal slurry component, and a corrosion inhibiting slurry component can then dispensed onto the pad (e.g., pad 109, 209). After a third predetermined amount of time has elapsed, the timed sequence can start over again by again dispensing the first slurry components. The sequence can be repeated as many times as necessary to accomplish the desired results, such as a desired amount of film removal. Following the polishing sequence, the pad 109, 209 can be rinsed by supplying rinsing liquid thereto.

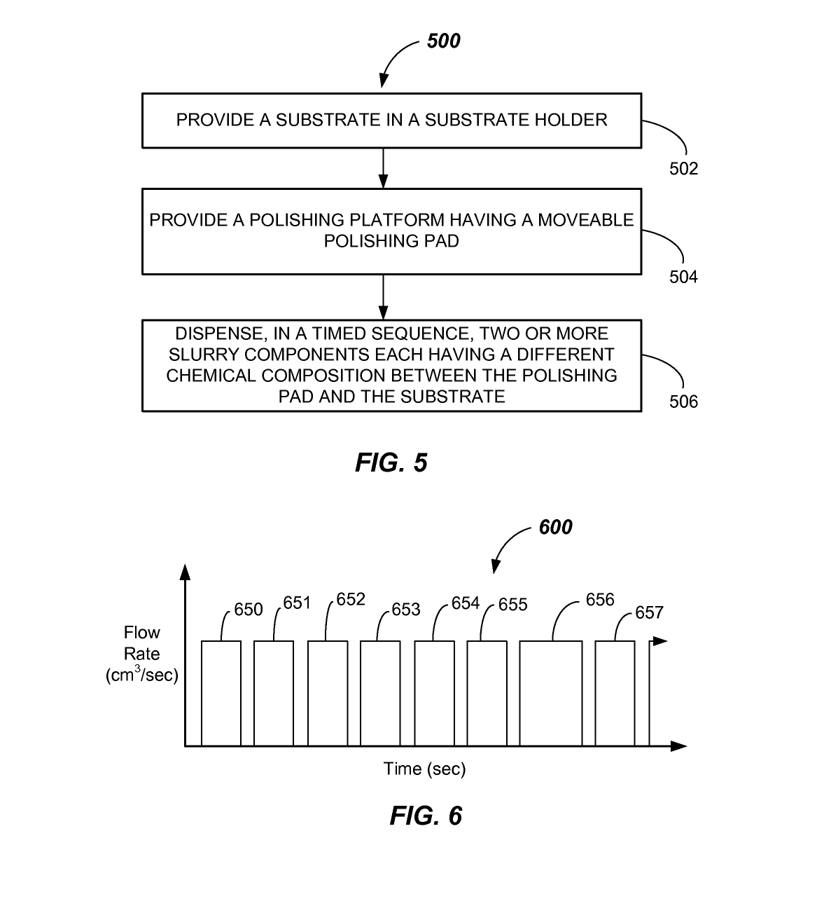

FIGS. 5 and 6 illustrate another method 500 of polishing a substrate. The method 500 includes, in 502, providing a substrate (e.g., substrate 101) in a substrate holder (e.g., holder 120, 220), and, in 504, providing a polishing platform having a moveable polishing pad. In 506, the method includes dispensing, in a timed sequence, two or more slurry components each having a different chemical composition between the polishing pad and the substrate.

As shown in FIG. 6, the slurry components can be dispersed between the pad (e.g., pad 109, 209) and the substrate 101 in a timed sequence as shown. In a first time increment 650, a first slurry component (e.g., an oxidizing slurry component) can be supplied. This is followed by a second slurry component (e.g., a material removal slurry component) for a second time increment 651. The chemical composition of the first and second slurry components are different. This can be followed by providing a third slurry component (e.g., a corrosion inhibiting slurry component) for a third time increment 652. Two or more of these dispensing phases can be repeated in 653-655. Other phases can be performed in addition or in substitution thereof. The three- or more dispense sequences can be repeated over and over as many times are desired on a single substrate. This can be performed while the substrate is being oscillated and rotated against the moving pad (e.g., pad 109, 209) as described above. After these polishing phases are completed, the pad (e.g., pad 109, 209) can undergo a rinsing phase wherein the pad (e.g., pad 109, 209) can be supplied with a rinsing liquid (e.g., DI water or other inert liquid solution) in 656. The disbursing of the rinsing liquid (e.g., de-ionized water) can be used to dilute the last applied chemistry. The method 500 can then stop, a new substrate can be placed in the substrate holder (e.g., substrate holder 120, 220), and the described method 500 can be implemented on the second substrate starting at 657.

Each of the phases can take between about 1 second and about 60 seconds. Other time lengths can be used. Some of the pulses can be less than 1 second. Each phase can be of the same or a different length. Some of the slurry components can be combined in some embodiments to institute more than one processing phase in a single pulse. For example, an oxidation and corrosion inhibitor phase can be combined as one slurry component and provided as one pulse in some embodiments. In other embodiments, a complexing agent can be combined in a single pulse with an abrasive (e.g., a metal oxide abrasive). The oxidizing agent can be hydrogen peroxide. The corrosion inhibitor can be triazole. The complexing agent can be an organic acid, organic acid salt, or an amino acid. Other types of oxidizing agents, corrosion inhibitors, complexing agents, and abrasives can be used.

FIG. 6 illustrates another embodiment of a method 600 utilizing a series of slurry components that are disbursed in a timed sequence (e.g., as pulses of individual slurry components). The use of time-separated introduction of polishing chemistry allows for increased flexibility in use of chemical agents (e.g., two or more slurry components). For example, oxidation chemistries are generally self-limiting. A surface film can be oxidized to a depth of about 20 angstroms and then stopped. By separating the slurry components in time, more aggressive oxidation chemistries could be used where the depth of oxidation can be controlled by the length of the pulse of chemical slurry component supplied to the substrate.

In particular, individual phases can be instituted to affect specific reactions to form a modified layer on the surface of the substrate. In some conventional material removal processes, systems use slurry additives which can suppress removal at lower polishing pressures. These prior polishing systems can provide better control of within die (WID) thickness because removal rates drops dramatically once topography has been removed. As a result, topography in regions of a die with low density is quickly removed and then the dielectric removal stops while topography removal in other regions of the die continues to polish until they are planarized. However, these systems suffer from very low removal rates (by design) once the main topography has been planarized. They can also suffer from large features being incompletely removed. A multi-step method according to an aspect of the invention having phased (e.g., timed) introduction of the slurry components (e.g., additive, abrasive without additive, and possibly interspersed and/or followed by a rinse) can be use to overcome these previous limitations. For example, the additive could be first introduced, followed by an abrasive solution which dilutes the additive and enables limited film removal. Additional removal could be accomplished by introduction of rinse which can quickly dilute the additive and allows limited removal of film until the charge of abrasive slurry component is exhausted.

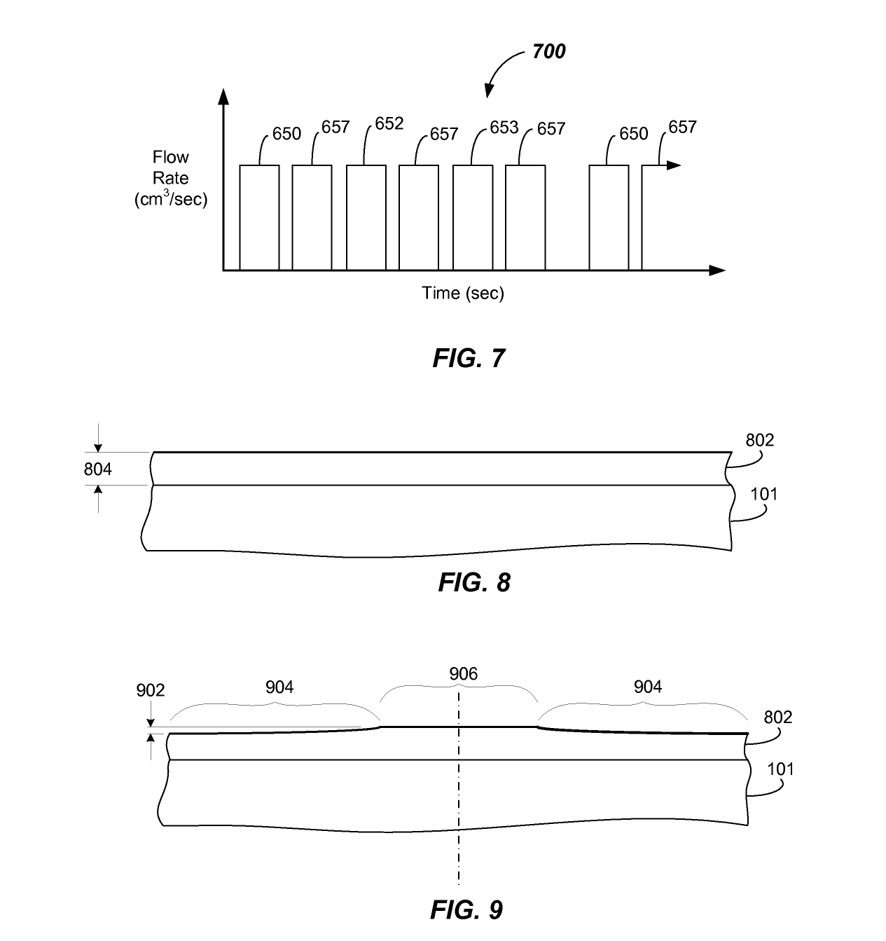

An example of the multi-step method and system is provided below. The method can be useful for metal film removal, and can involve an oxidation phase involving film oxidation, and a phase of inhibitor adsorption and complexing agent aided abrasion of the oxidized surface, which are executed in a serial manner to achieve film removal per reaction cycle. In this embodiment, each of the slurry components can be dispersed between the pad (e.g., pad 109, 209) and the substrate 101 in a timed sequence, but with a rinsing phase being instituted between the disbursement of each slurry component, as shown in FIG. 7. Thus, each pulse of a slurry component (e.g., oxidizing, inhibitor, complexing agent, material removal agent) can be separated by a pulse of a rinsing agent (e.g., DI water) to rinse the surface of the pad (e.g., pad 109, 209) and substrate 101.

In particular, in a first time increment 650, a first slurry component (e.g., an oxidizing slurry component) can be supplied. This is followed by a rinse in 657. Then a second slurry component (e.g., a material removal slurry component) can be disbursed for a second time increment 652. This can be followed by another rinse in 657. The chemical composition of the first and second slurry components are different. This second rinse 657 can be followed by a third slurry component (e.g., a corrosion inhibiting slurry component) for a third time increment 653. This can be followed by another rinse in 657. After this sequence is completed, it can be repeated again on the same substrate 101 as many times as desired to achieve the desired material removal, or a new substrate can be inserted in the substrate holder (e.g., 120, 220) and polishing of the substrate by the method 700 can commence on the new substrate. The times can be the same or different for each phase of the polishing process.

Other steps can be used in the sequence, such as an inhibitor adsorption phase, and complexation-abrasion phase. Two or more of the phases can be combined in some embodiments. The relative duration of each phase can be determined based on reaction kinetics of that particular phase. For example, an oxidation phase can be relatively short for copper polish, while it can be relatively long for polishing ruthenium or more noble metals. The pulse duration of a corrosion inhibitor phase (including inhibitor adsorption) can also be varied in length based on the kinetics of adsorption. Likewise, a complexation-abrasion phase can be varied in length based on the kinetics thereof. In some embodiments, a pulse of an oxidizing slurry component (e.g., an oxidizing solution) can be followed by a pulse of a corrosion inhibitor slurry component (e.g., an inhibitor solution), and then followed by a pulse of a complexing slurry component (e.g., a complexing agent). These sequenced pulses can be provided while the substrate 101 is being pressed against a moving surface of the pad (e.g., pad 109, 209).

Another example of a phased instruction of the slurry components in a timed sequence is as follows. A copper film removal process is provided wherein a first pulse of combined slurry component of an oxidizer and inhibitor solution are followed by a separate pulse of a complexing agent, while the substrate (e.g., wafer) is being pressed against a moving surface of the pad (e.g., pad 109, 209) as described herein. In some embodiments, the pulse of combined slurry components of oxidizer and inhibitor solution and the separate pulse of complexing agent can be interspersed by a rinsing pulse of a rinsing liquid. Optionally, the rinse pulse can be at the end of the two-phase sequence.

In another method embodiment adapted to metal oxide film polishing and removal, a two-phase method includes a first pulse of an oxidizing slurry component that can be followed by a separate sequential pulse of a combined slurry component having a metal oxide abrasive and a complexing agent. Optionally, the complexing agent slurry component and the metal oxide abrasive slurry component can be instituted as separated phases one after the other in a three-phase polishing process. A rinsing phase can be instituted between the phases or at the end of the sequence.

One significant advantage of the time sequence introduction of slurry components is that each step or pulse can be self-limiting, which can lead to relatively more uniform removal of even small thicknesses, particularly less than 500 Angstroms, and especially less than 200 Angstroms. For example, once a surface oxidation phase of a surface (e.g., a copper surface) is completed to several atomic layers (between about 25-30 Angstroms), the oxidation rate can slow dramatically. Consequently, when the complexation-abrasion phase is next executed, film removal can be automatically limited to about 25 to 30 Angstroms, regardless of the length of the phase and film removal uniformity can be made to be relatively independent of removal rate.

In each of the described methods herein, the distribution of the slurry components can be provided by the systems and apparatus described herein. Optionally, other suitable systems adapted to carry out a timed sequence delivery of the slurry components, and possibly a rinse, can be used.

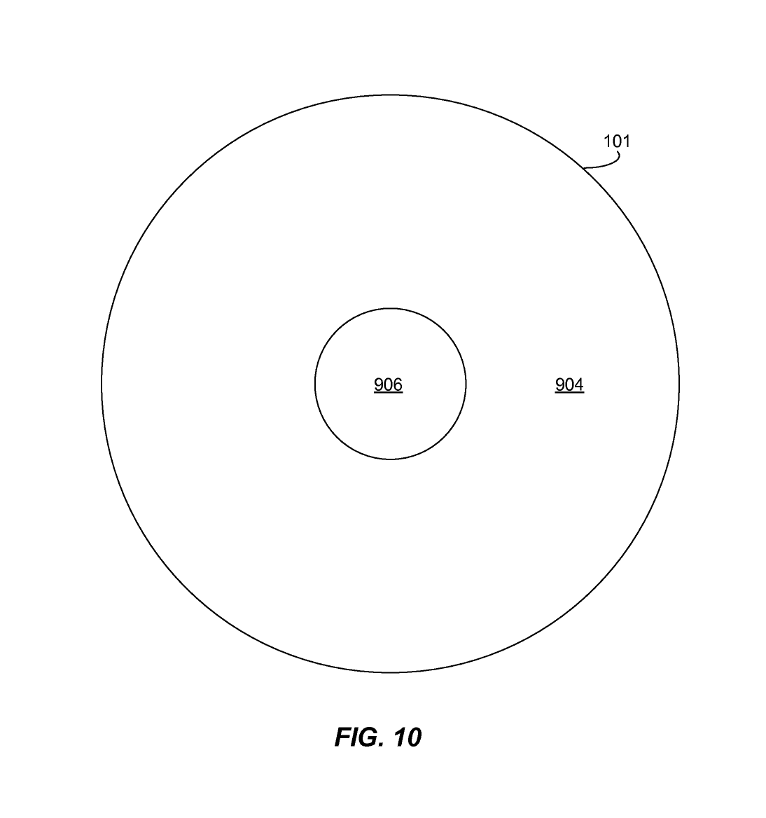

Turning now to FIGS. 8 and 9, an example before and after cross-sectional profile of a portion of a substrate 101 that was intentionally polished non-uniformly according to embodiments of the present invention is depicted. In FIG. 8, before the non-uniform polishing, the film 802 on the substrate 101 has a relatively uniform thickness 804. As depicted in FIG. 9, after application of the non-uniform ALP methods of the present invention, the film 802 has been reduced in thickness by a desired amount 902 in the target material removal area 904 while the film 802 remains at the original thickness 804 in the non-target area 906. FIG. 10 depicts a top view of the substrate 101 after the non-uniform polishing illustrating the target material removal area 904 and the non-target area 906. Note that the diameter of the non-target area 906 can be any desired size as will be described in further detail below.

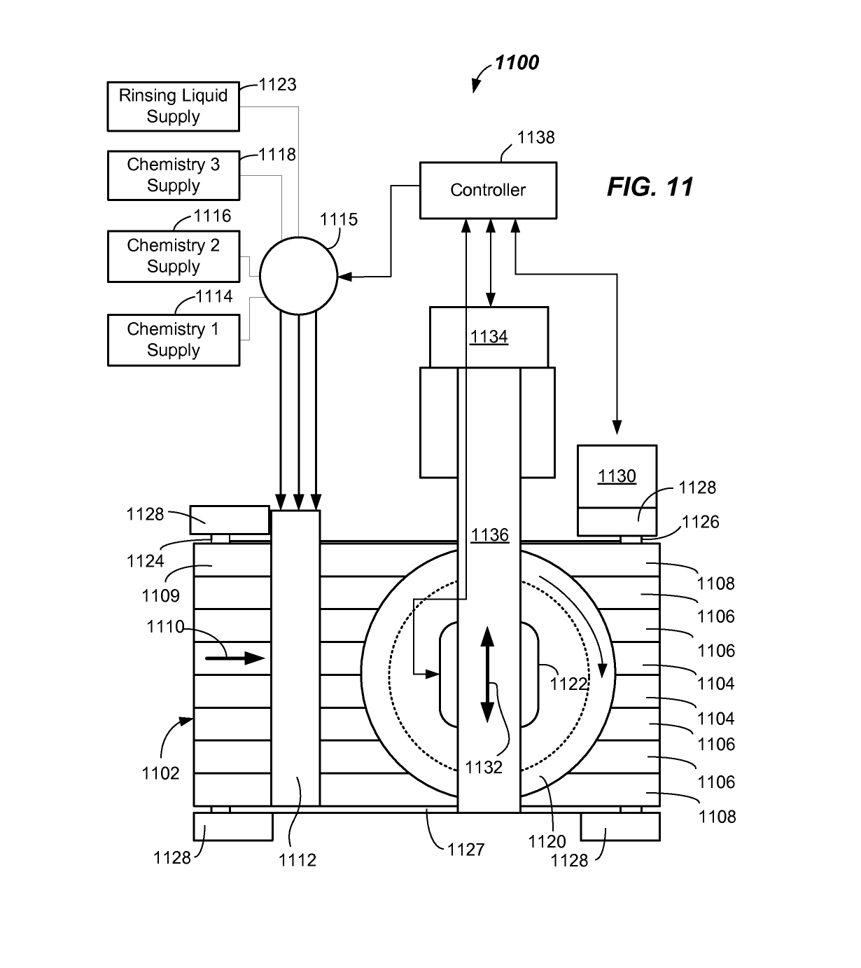

FIG. 11 illustrates an example of a non-uniform substrate polishing apparatus 1100 similar to the example substrate polishing apparatus 100 described above but adapted to remove more layers of a target material removal area 904 (FIG. 9) while not removing material from a non-target area 906 (FIG. 9). The example non-uniform substrate polishing apparatus 1100 is adapted to hold and polish a substrate 101 as described above with respect to FIGS. 8 to 10. The non-uniform substrate polishing apparatus 1100 includes a polishing platform 1102 having two or more physical zones, such as first zone 1104, second zone 1106, and third zone 1108. The two or more zones (e.g., 1104, 1106, and 1108) are adapted to contain a different slurry chemistry having a different chemistry (chemical composition). The two or more zones can be arranged across the width of the platform 1102. In the depicted example embodiment, eight zones are shown. However, more or less numbers of zones can be provided. In various embodiments, there can be multiple zones that are non-adjacent, but that contain a slurry chemistry having the same chemistry. In the depicted embodiment, the platform 1102 comprises a linear polishing platform wherein the two or more zones are arranged across a width of a pad 1109 and that extend along the length of the pad with the length being substantially larger than the width. In the depicted embodiment, the pad 1109 of the platform 1102 moves linearly as indicated by directional arrow 1110.

During the polishing method, various slurry chemistries, such as slurry chemistry 1, slurry chemistry 2, and slurry chemistry 3 can be applied to the pad 1109 by a distributor 1112. The distributor 1112 can have any suitable internal structure capable of dispensing the slurry components to the two or more zones (e.g., to zones 1104, 1106, 1108). The slurry chemistry 1, slurry chemistry 2, and slurry chemistry 3, for example, can be received from slurry chemistry supplies 1114, 1116, 1118, respectively. More or less numbers of slurry chemistries can be provided. The supply of slurry chemistries to the distributor 1112 can be accomplished by a distribution system having one or more suitable pumps, manifolds, valves, or other flow control mechanisms 1115 under the control of a controller 1138 (e.g., a processor, a computer, or other operations management system adapted to execute instructions adapted to implement methods disclosed herein).

The flow control mechanisms 1115 are further adapted to allow provision of any of the chemistries 1, 2, 3, or rinsing liquid or any combination thereof to any of the channels of the distributor 1112 at different times. Thus, in some embodiments, the non-uniform substrate polishing apparatus 1100 can deliver any combination of any of the slurry chemistries, slurry components, and rinsing liquid to any of number or arrangement of desired zones (e.g., to zones 1104, 1106, 1108) at any given time. “Slurry chemistry” as used herein is intended to mean one or more slurry components that is capable of being used to perform material removal (e.g., at various different rates) from, or material preservation on, a substrate. In some embodiments, a rinsing liquid (e.g., de-ionized water) can be provided from the rinsing liquid source 1123 and be inserted between two or more of the zones, such as between zone 1104 and 1106, or between 1106 and 1108, or between both zones 1104 and 1106 and zones 1106 and 1108. Any suitable construction of the distributor 1112 can be used to accomplish this separation of the zones 1104, 1106, 1108 by a rinsing liquid zone.

For example, in one or more embodiments, slurry chemistry 1 can include material adapted to execute a corrosion inhibition function. Slurry chemistry 1 can include a liquid carrier such as purified water, and corrosion inhibitor such as benzotriazole, or 1,2,4 Triazole. Slurry chemistry 1 can be supplied from the chemistry 1 supply 1114 to the first zone 1104 of the pad 1109 by a first channel of the distributor 1112, for example.

Slurry chemistries 2 and 3 can include materials adapted to concurrently execute both a surface modification function and a material removal function. For example, the surface modification function can include oxidation or other surface modification such as the formation of a nitride, bromide, chloride, or hydroxide containing layer. Slurry chemistries 2 and 3 can include a liquid carrier such as purified water, and an oxidant such as hydrogen peroxide, ammonium persulfate, or potassium iodate. Other surface modifying materials can be used. Slurry chemistries 2 and 3 can also include an abrasive media such as silicon dioxide or aluminum oxide. The abrasive can have an average particle size between about 20 nanometers and 0.5 microns. Other particle sizes can be used. Slurry chemistries 2 and 3 can also include an etchant material such as carboxylic acid, or an amino acid. Other etchant or complexing agent materials can be used.

In some embodiments, slurry chemistries 2 and 3 can be the same and, in other embodiments, chemistry 3, for example, can include a more aggressive etchant and/or abrasive to remove material at a faster rate than chemistry 2. Such embodiments enable creating target material removal areas with different film thicknesses. Slurry chemistries 2 and 3 can be supplied to the second zone 1106 and third zone 1108 of the pad 1109 from the chemistry 2 supply 1116 and the chemistry 3 supply 1118 through a second and third channel of the distributor 1112, for example.

The zones 1104, 1106, 1108 can be arranged in a side by side fashion and can each have a width of between about 2 mm and 50 mm. The widths can be the same as or different from each other. Other widths can be used.

In one or more embodiments, a distribution system including a distributor 1112 is adapted to dispense into the two or more zones (e.g., zone 1104, 1106) at least two different slurry chemistries. In some embodiments, the slurry chemistries can be selected from a group consisting of a material preservation slurry chemistry, a slow material removal slurry chemistry, and an aggressive material removal chemistry, as discussed above.

In one or more embodiments, the distributor 1112 can be formed as a unitary component and can be positioned adjacent to the pad 1109 (e.g., just above the pad 1109). The distributor 1112 can provide delivery of the slurry chemistries concurrently through two or more outlets. For example, the distributor 1112 can be part of a distribution system that can include multiple channels.

In some embodiments, the rinsing liquid can be received in a separate separation zone to separate the disbursed slurry components. The outlets can have a diameter of less than about 5 mm, or between about 1 mm and 15 mm in some embodiments. A pitch (e.g., spacing between the adjacent outlets) can be less than about 50 mm, less than about 25 mm, or even less than about 10 mm in some embodiments. In some embodiments, the pitch can be between about 2 mm and 50 mm. Other diameters and pitches can be used.

In other embodiments, the distributor can be comprised of separate distributor heads, one for each slurry chemistry that can be arranged at different spatial locations on the pad 1109. A rinsing liquid (e.g., DI water) can be delivered through some or all of the outlets, or through separate outlets specifically designed for the rinsing liquid. Rinsing liquid can be provided from rinsing liquid supply 1123 to some or all of each of the outlets. Optionally, the rinsing liquid can be provided by a separate distributor head or separate outlets from the distributor 1112.

In some embodiments, the distributor can be included in the pad support 1127 of the platform 1102. In such embodiments, the slurry chemistries 1, 2, 3 can be dispensed to the various zones 1104, 1106, and 1108 from underneath or through the pad 1109. The pad support 1127 can include holes like the outlets in distributor 1112 being arranged across the width of the pad 1109. Each hole can be fluidly couplable to one of the slurry chemistry supplies 1114, 1116, 1118. The various separated slurry chemistries 1, 2, 3 can pass though the holes and wick through the pad 1109 containing an internal porous structure of connected open pores as the pad 1109 is rotated on the rollers 1124, 1126. The wicking provides the slurry chemistries 1, 2, 3 to the one or more zones 1104, 1106, 1108, respectively. Rinsing liquid can also be disbursed through some or all of the holes.

Still referring to FIG. 11, as the slurry chemistries are being supplied to the zones 1104, 1106, 1108 of the pad 1109, a substrate holder 1120 of the non-uniform substrate polishing apparatus 1100 can be rotated. Substrate holder 1120 is adapted to hold the substrate in contact with the pad 1109 and rotate the substrate as the polishing takes place. Other motions can be provided in addition or in place of the rotation, such as orbital motion. In some embodiments, rotational speed can be between about 10-150 RPM, for example. Other speeds can be used. Rotation can be accomplished by driving the holder 1120 with a holder motor 1122. Any suitable motor can be used. An applied pressure on the substrate during polishing can be between about 0.1 psi and 1 psi, for example. Other pressures can be used. Any suitable conventional mechanism for applying the pressure can be used, such as a spring-loaded mechanism or other suitable vertically-acting actuator. Substrate holders (also referred to as retainers or carrier heads) are described in U.S. Pat. No. 8,298,047; U.S. Pat. No. 8,088,299; U.S. Pat. No. 7,883,397; and U.S. Pat. No. 7,459,057, issued to the present assignee, for example.

As the slurry components 1, 2, 3 are applied to the respective zones 1104, 1106, 1108, the pad 1109 can be moved in the direction of the arrow 1110. The linear speed of movement of the pad 1109 in the direction of arrow 1110 can be between about 40 cm/sec and about 600 cm/sec, for example. Other speeds can be used. The pad 1109 can be provided in the form of a continuous or endless belt. The pad 1109 can be supported at its ends by rollers 1124, 1126 (e.g., cylindrical rollers) and underneath the top portion of the pad 1109 by a pad support 1127 spanning the width of the pad 1109. Rollers 1124, 1126 can be supported for rotation on a frame 1128 by bearings or bushings, or other suitable low friction devices, for example. One of the rollers, such as roller 1126, can be coupled to a pad drive motor 1130 which can be driven at the appropriate rotational speed to accomplish the linear polishing speed of the pad 1109 described above. Pad support 1127 can also be coupled to the frame 1128 at one or more locations and can support the upper portion of the pad 1109 underneath some or most of the length of the upper surface of the pad 1109.

In addition to the rotation of the substrate holder 1120, and the motion of the pad 1109, the holder 1120 can be translated in the direction of directional arrow 1132. The translation can be an oscillation back and forth along the transverse direction 1132, generally perpendicular to the linear motion of the pad 1109. Unlike in the operation of the substrate polishing apparatus 100 described above with respect to FIG. 1A, any translation of the holder 1120 in the operation of the example non-uniform substrate polishing apparatus 1100 will be limited so as to avoid removing material from the non-target area. However, in some embodiments, translation of the holder 1120 can be used to adjust the size of the target material removal area or initial positioning of the substrate relative to the zones.

Translation can be effected using any suitable translation motor 1134 and drive system (not shown) that moves the substrate holder 1120 back and forth along a support beam 1136. The drive system adapted to accomplish the translation can be a rack and pinion, chain and sprocket, belt and pulley, drive and ball screw, or other suitable drive mechanism. In other embodiments, an orbital motion can be provided by a suitable mechanism. The rotation of the pad 1109, rotation and translation (e.g., oscillation) of the substrate holder 1120, and the distribution flow of the slurry chemistries 1, 2 and 3 and rinsing liquid 1123 can be controlled by controller 1138. Controller 1138 can be any suitable computer and connected drive and/or feedback components adapted to control such motions and functions.

The pad 1109 can be made of a suitable polishing pad material, for example. The pad 1109 can be a polymer material, such as polyurethane, and can have open surface porosity. Surface porosity can be open porosity and can have an average pore size of between about 2 microns and 100 microns, for example. Pad can have a length, as measured between the centers of the rollers 1124, 1126, of at least between about 30 cm and 300 cm, for example. Other dimensions can be used.

Analogous to the embodiment depicted in FIGS. 2A and 2B, a rotational polishing pad embodiment of a non-uniform substrate polishing apparatus can be used. As with the linear polishing pad example embodiment depicted in FIG. 11, different zones (albeit concentrically arranged instead of a parallel arrangement) can be defined and adapted to receive different slurry chemistries at different times to facilitate removal of different amounts of material from one or more select target areas of the substrate. Thus, as with the linear polishing pad example embodiment depicted in FIG. 11, a rotational polishing pad embodiment of a non-uniform substrate polishing apparatus can be used to create a film profile with two or more thicknesses (e.g., as shown in FIG. 9).

In some alternative embodiments, a rotating polishing pad smaller than the substrate can be used and material can be removed using localized motion of the pad in the presence of slurry applied though portions of the pad or applied directly to the substrate at different times corresponding to different positions of the pad. For example, by only applying removal chemistry to a center area of a rotating polishing pad smaller than the substrate and positioned at the center of the rotating substrate, the effective diameter of pad for removing material can be made smaller than the polishing pad's actual diameter. Further, if a smaller polishing pad is disposed at an offset from the center of a rotating substrate, a ring-shaped area between an inner radius and an outer radius can be isolated for material removal. The width of the ring-shaped removal area can be further controlled based upon the radius of the pad area to which removal chemistry is applied and/or by varying the offset from the center of the substrate (e.g., by radially oscillating the rotating pad).

In other example embodiments, different chemistries can be applied at different times corresponding to different positions of the pad relative to the center of the substrate for selective removal of material. Thus, for example, a chemistry adapted for aggressive removal of material can be applied to the substrate when the pad is positioned in the center of the rotating substrate and a chemistry adapted for relatively gentle removal of material can be applied to the substrate when the pad is positioned away from the center. This example arrangement allows forming a film profile that is thinner in the center of the substrate and thicker at the edge of the substrate (e.g., opposite of the profile depicted in FIG. 9).

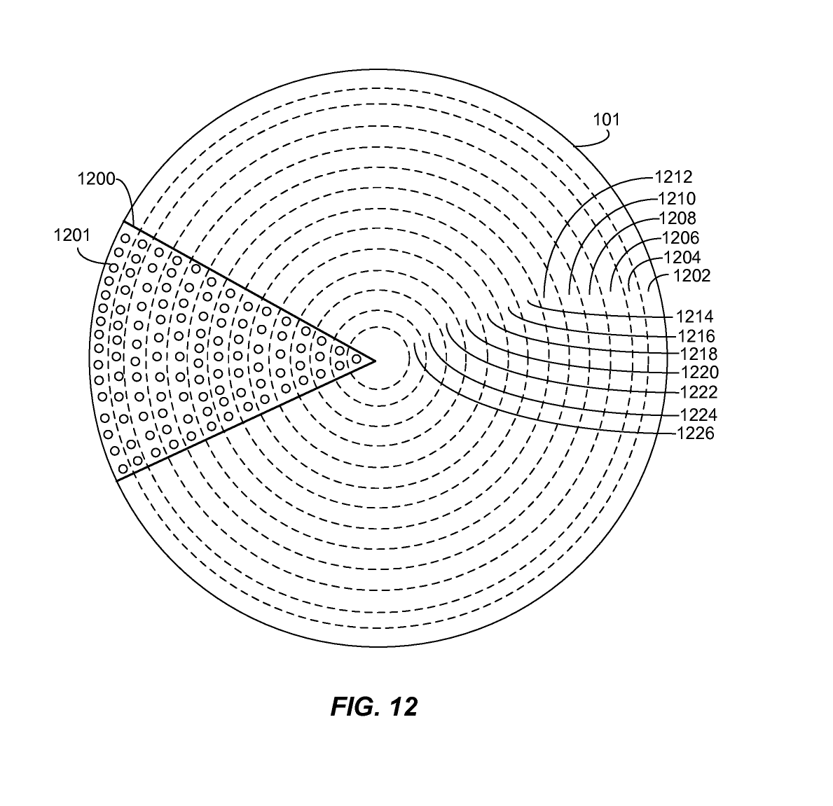

In some other alternative embodiments, stationary polishing pads having shapes other than a circular shape can be used. For example, in order to compensate for the varying speed of rotation at different radii of a rotating substrate, a stationary wedge-shaped pad 1200 as depicted in FIG. 12 can be used to polish a film on a rotating substrate 101 to a uniform thickness. In other words, a wedge-shaped pad 1200 can be used to insure that substrate area rotating relatively quickly (e.g., at a large radius nearer the outer edge, for example, substrate zones 1202-1212) experiences exposure to removal chemistry on the pad 1200 equal to area moving relatively slowly (e.g., at a small radius nearer the center of the rotating substrate 101, for example, substrate zones 1214-1226). In some embodiments, the wedge-shaped pad 1200 can include an arrangement of slurry delivery pores 1201 or channels disposed to dispense an amount of slurry in proportion to the circumference of the substrate zone 1202-1226 being polished.

In non-uniform polishing applications, a stationary wedge-shaped pad 1200 as depicted in FIG. 12 can be used to create film profiles with different desired thicknesses at each substrate zone 1202-1226 based on the chemistry of the slurry delivered to the pores 1201 corresponding to each substrate zone 1202-1226. In other words, a chemistry having a first function can be applied to a group of pores that only contacts a particular substrate zone (e.g., substrate zone 1202). Concurrently, a chemistry having a second function can be applied to a group of pores that only contacts a different substrate zone (e.g., substrate zone 1204). Concurrently, a chemistry having a third function can be applied to a group of pores that only contacts yet a different substrate zone (e.g., substrate zone 1206) and so on. Therefore, each substrate zone 1202-1226 can be subjected to a different chemistry to create a desired film thickness profile. Further, different chemistries can be applied at different times to different substrate zones.

In some embodiments, a non-uniform substrate polishing apparatus can be used to perform various methods 1300 of the present invention. While a substrate is rotated against a moving polishing pad (1302), different chemistries having different functions are applied separately to at least two different zones of the polishing pad (1304). Different amounts of material are removed from the substrate corresponding to the at least two different zones of the polishing pad (1306). The polishing pad can be a linear moving pad or a rotating pad. In some embodiments, the resulting film thickness profile on the substrate can have a plurality of thicknesses.

Accordingly, while the present invention has been disclosed in connection with example embodiments thereof, it should be understood that other embodiments can fall within the scope of the invention, as defined by the following claims.

The invention claimed is:

1. A non-uniform substrate polishing apparatus, comprising:
a polishing pad having two or more zones, each zone adapted to apply a different slurry chemistry to a different area on a substrate to create a film thickness profile on the substrate having at least two different film thicknesses.

2. The substrate polishing apparatus of claim 1, including a linear polishing platform wherein the two or more zones are arranged across a width.

3. The substrate polishing apparatus of claim 1, including a rotary polishing platform wherein the two or more zones are arranged as concentric annuli.

4. The substrate polishing apparatus of claim 1, including a distributor adapted to dispense at least two of the different slurry chemistries to the two or more zones.

5. The substrate polishing apparatus of claim 4, wherein the distributor includes a first set of outlets adapted to dispense a first slurry chemistry to one of the two or more zones, and a second set of outlets adapted to dispense a second slurry component to another of the two or more zones.

6. The substrate polishing apparatus of claim 1, wherein each zone has a width of about 2 mm or more.

7. The substrate polishing apparatus of claim 1, wherein a first zone has a chemistry applied having a material preservation function.

8. The substrate polishing apparatus of claim 1, wherein a first zone has a chemistry applied having a material removal function.

9. The substrate polishing apparatus of claim 1, wherein a first zone has a chemistry applied having a relatively aggressive material removal function and a second zone has a chemistry applied having a relatively gentle material removal function.

10. The substrate polishing apparatus of claim 1, wherein a first zone and a second zone include slurry chemistries having different chemical compositions.

11. The substrate polishing apparatus of claim 1, including a distribution system adapted to dispense into the two or more zones at least two different slurry chemistries selected from a group consisting of:
a material preservation slurry chemistry,
a slow material removal slurry chemistry, and
an aggressive material removal chemistry.

12. The substrate polishing apparatus of claim 1, wherein a rinsing liquid zone is dispensed between the two or more zones.

13. A substrate polishing system, comprising:
a controller including a processor and a memory adapted to store instructions adapted to operate the substrate polishing system;
a substrate holder adapted to hold a substrate; and
a polishing pad having two or more zones, each zone adapted to apply a different slurry chemistry to a different area on the substrate to create a film thickness profile on the substrate having at least two different film thicknesses,
wherein the substrate holder is adapted to rotate the substrate against the polishing pad under the direction of the controller.

14. The substrate polishing system of claim 13, including a linear polishing platform wherein the two or more zones are arranged across a width.

15. The substrate polishing system of claim 13, including a rotary polishing platform wherein the two or more zones are arranged as concentric annuli.

16. The substrate polishing system of claim 13, including a distributor adapted to dispense at least two of the different slurry chemistries to the two or more zones.

17. The substrate polishing system of claim 16, wherein the distributor includes a first set of outlets adapted to dispense a first slurry chemistry to one of the two or more zones, and a second set of outlets adapted to dispense a second slurry component to another of the two or more zones.

18. The substrate polishing system of claim 13, wherein each zone has a width of about 2 mm or more.

19. A method of polishing a substrate, comprising:
rotating a substrate in a substrate holder against a moving polishing pad;
applying different slurry chemistries having different functions separately to at least two different zones of the polishing pad; and
removing different amounts of material from different areas of the substrate corresponding to the at least two different zones of the polishing pad.

20. The method of claim 19 wherein applying different slurry chemistries includes applying different slurry chemistries having different material removal rates.
